(19) United States
(12) Patent Application Publication
(10) Pub. No.: US 2026/0165002 A1
(43) Pub. Date: Jun. 11, 2026

(54) DISPLAY MODULE AND DISPLAY APPARATUS

(71) Applicant: BOE Technology Group Co., Ltd., Beijing (CN)

(72) Inventors: Yue CUI, Beijing (CN); Hong ZHU, Beijing (CN); Xiangdong LI, Beijing (CN)

(21) Appl. No.: 18/705,996

(22) PCT Filed: May 8, 2023
(86) PCT No.: PCT/CN2023/092823

§ 371 Date: Apr. 30, 2024

(30) Foreign Application Priority Data
May 11, 2022 (CN) 202210515416.1

(51) Int. Cl. H10K 59/80; H10K 59/35; H10K 102/00

(52) U.S. Cl. CPC H10K 59/878; H10K 59/351; H10K 2102/311

(57) ABSTRACT

A display module (200) and a display apparatus. The display module (200) comprises: a display panel (202); and an optical film layer (300), which is arranged on a light emission side of the display panel (202), wherein the optical film layer (300) comprises at least two first optical layers (302) and at least one second optical layer (304), which are arranged in a stacked manner; and the first optical layer (302) and the second optical layer (304) are alternately arranged, and the refractive index of the first optical layer (302) is less than the refractive index of the second optical layer (304).

### CROSS-REFERENCE TO RELATED APPLICATIONS

The present application is a U.S. National Phase Entry of International Application No. PCT/CN2023/092823 having an international filing date of May 8, 2023, which claims priority to Chinese Patent Application No. 202210515416.1, filed to the CNIPA on May 11, 2022 and entitled “Display Module and Display Apparatus”. Contents of the above-identified applications should be regarded as being incorporated herein by reference.

### TECHNICAL FIELD

Embodiments of the present disclosure relate to, but are not limited to, the field of display technologies, and particularly relate to a display module and a display apparatus.

### BACKGROUND

Display technology is a technology that uses electronic technology to provide flexibility for visual information. With the development of display technology, various display products emerge one after another. Display screens, which are initially used only for televisions and computers, now appear in various types of hardware devices, for example, smart watches, smart switches, smart remote controls and so on.

Products like smart watches, smart switches and smart remote controls also hope to keep their aesthetic appearances when the display screens are not lit up, which challenges the display technology.

### SUMMARY

The following is a summary of subject matters described in the present disclosure in detail. This summary is not intended to limit the protection scope of claims.

An embodiment of the present disclosure provides a display module, including: a display panel; and an optical film layer arranged on a light emission side of the display panel. The optical film layer includes at least two first optical layers and at least one second optical layer which are arranged in a stacked manner, the first optical layers and the second optical layer are alternately arranged, and a refractive index of a first optical layer is less than a refractive index of the second optical layer.

In an exemplary implementation, an ink layer and a cover plate are further included. The ink layer is arranged on the light emission side of the display panel, the optical film layer is arranged on a side of the ink layer away from the display panel, and the cover plate is arranged on a side of the optical film layer away from the ink layer.

In an exemplary implementation, the refractive index of the first optical layer is 1.4 to 1.6, and the refractive index of the second optical layer is 1.9 to 2.1.

In an exemplary implementation, the refractive index of the first optical layer is 1.5, and the refractive index of the second optical layer is 2.0.

In an exemplary implementation, a fabrication material of the first optical layer is silicon oxide, and a fabrication material of the second optical layer is silicon nitride.

In an exemplary implementation, the optical film layer includes at least three first optical layers and at least two second optical layers, and an optical layer of the optical film layer away from the display panel and an optical layer of the optical film layer close to the display panel are both the first optical layers.

In an exemplary implementation, the thickness of the first optical layer away from the display panel and the thickness of the first optical layer close to the display panel are equal.

In an exemplary implementation, the first optical layer away from the display panel and the first optical layer close to the display panel are configured to change the color of the reflected light on the optical film layer by adjusting thickness.

In an exemplary implementation, the thickness of the first optical layer away from the display panel and the thickness of the first optical layer close to the display panel are greater than or equal to 135 nm.

In an exemplary implementation, the thicknesses of the second optical layers and the thickness of the first optical layer sandwiched between the second optical layers are each less than the thickness of the first optical layer away from the display panel.

In an exemplary implementation, the optical film layer further includes a transflective film on a side close to the ink layer, and the transflective film is configured to perform semi-transmissive and semi-reflective optical processing on passing light so as to enhance specularity of the optical film layer.

In an exemplary implementation, the color of the ink layer is the same as the color of a display product corresponding to the display module.

In an exemplary implementation, the color difference between a center part and an edge part of a light emission surface of the display module is less than 1.

In an exemplary implementation, the display product is gold, a brightness L in color difference values is 65 to 66, a red-green channel value a is 9 to 10, and a yellow-blue channel value b is 26 to 27 at a center part of a light emission surface of the display module; and a brightness L in color difference values is 65 to 66, a red-green channel value a is 9 to 10, and a yellow-blue channel value b is 28 to 29 at an edge part of the light emission surface of the display module.

In an exemplary implementation, the display product is white, a brightness L in color difference values is 81 to 82, a red-green channel value a is 0 to 1, and a yellow-blue channel value b is −2 to −3 at a center part of a light emission surface of the display module; and a brightness L in color difference values is 82 to 83, a red-green channel value a is 0 to 1, and a yellow-blue channel value b is −2 to −3 at an edge part of the light emission surface of the display module.

In an exemplary implementation, the optical film layer is a mirror film.

In an exemplary implementation, the display panel is an organic light emitting diode display panel and the cover plate is made of a flexible material.

An embodiment of the present disclosure provides a display apparatus which includes any one of the above display modules.

Other aspects of the present disclosure may be comprehended after the drawings and the detailed descriptions are read and understood.

### BRIEF DESCRIPTION OF DRAWINGS

FIG. 1A shows a schematic diagram of an exemplary hardware device 100.

FIG. 1B shows a reflectivity profile of an exemplary display apparatus.

FIG. 2 shows a schematic diagram of a structure of an exemplary display module 200 provided by an embodiment of the present disclosure.

FIG. 3A shows a schematic diagram of a structure of an exemplary optical film layer 300 according to an embodiment of the present disclosure.

FIG. 3B shows a schematic diagram of a structure of another exemplary optical film layer 300 according to an embodiment of the present disclosure.

FIG. 3C shows a schematic diagram of color control of the display module 200 provided by an embodiment of the present disclosure.

FIG. 3D shows a schematic diagram of optical principle of a display module 200 provided by an embodiment of the present disclosure.

FIG. 4 shows a diagram of display effect of a test sample.

### DETAILED DESCRIPTION

Specific implementations of the present disclosure will be described further in detail below with reference to the accompanying drawings and embodiments. The following embodiments are intended to illustrate the present disclosure and are exemplary only, but are not intended to limit the scope of the present disclosure. The embodiments and features in the embodiments of the present disclosure may be randomly combined with each other if there is no conflict.

Unless otherwise defined, technical terms or scientific terms used in the embodiments of the present disclosure shall have common meanings understood by people with ordinary skills in the field to which the present disclosure pertains. “First”, “second”, and similar terms used in the embodiments of the present disclosure do not represent any order, quantity, or importance, but are only used for distinguishing different components. “Include”, “contain”, or similar words mean that elements or objects appearing before the words cover elements or objects listed after the words and their equivalents, but do not exclude other elements or objects. “Connect”, “couple”, or similar words are not limited to a physical or mechanical connection, but may include an electrical connection, whether direct or indirect. “Upper”, “lower”, “left”, and “right”, etc., are only used for representing a relative positional relationship, and when an absolute position of a described object is changed, the relative positional relationship may also be correspondingly changed.

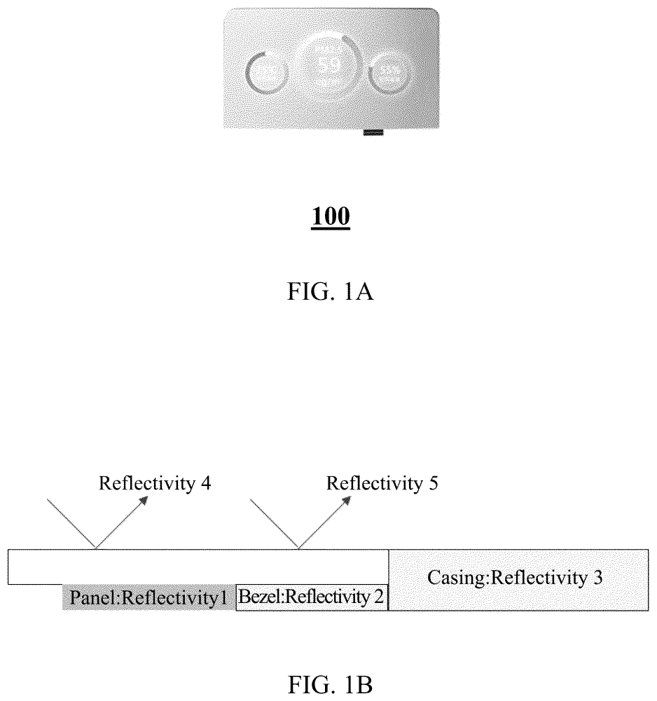

FIG. 1A shows a schematic diagram of an exemplary hardware device 100.

The hardware device 100, for example, may be an environmental monitoring device, may detect PM2.5, temperature, and humidity, and may display a detected data using a display screen.

The hardware device can be realized by using a white liquid crystal display (LCD). Generally, a white liquid crystal display has usually a structure of an LCD panel+a cover plate.

The cover plate is plated with a transflective film layer or film, which can achieve silvery-white effect. Although this design tries to approach the requirement of pure white around it, there will still be a color difference. Moreover, due to the combination of liquid crystal display and rigid cover plate, the thickness is relatively thick. In addition, because the rigid cover plate does not have flexability, the shape of such a device is not easy to change.

FIG. 1B shows a reflectivity profile of an exemplary display apparatus.

As shown in FIG. 1B, a panel, a bezel, a cover plate on a light emission side of the panel, the cover plate at a position corresponding to the bezel, and a casing of the display apparatus have corresponding reflectivity, with a total of five reflectivities.

Because reflectivities of different areas are different, colors of display area and non-display area are different.

As shown in FIG. 1B, in order to make the colors of a surface of the display apparatus in uniform, the effect is best when the reflectivity 4 is approximately equal to the reflectivity 5 and approximately equal to the reflectivity 3.

However, reflectivity 1 may affect reflectivity 4, while reflectivity 2 may affect reflectivity 5, and reflectivity 1 is not equal to reflectivity 2 and is not equal to reflectivity 3, and reflectivity 1 is relatively high, which makes it difficult to achieve the required uniformity in conventional design.

An embodiment of the present disclosure provides a display module, which includes a display panel; and an optical film layer arranged on a light emission side of the display panel. The optical film layer includes at least two first optical layers and at least one second optical layer arranged in a stacked manner, the first optical layers and the second optical layer are alternately arranged, and the refractive index of the first optical layer is less than that of the second optical layer.

By arranging an optical film layer on the light emission side of the display panel, and the optical film layer adopts first optical layers and a second optical layer which are alternately arranged and have different refractive indices, the transmission of a display screen of the display panel can be realized, and the display effect is better. Moreover, because of the collocation of the refractive indices of the optical layers, a better mirror effect is achieved to a certain extent, and the product surface has better uniformity and is aesthetic.

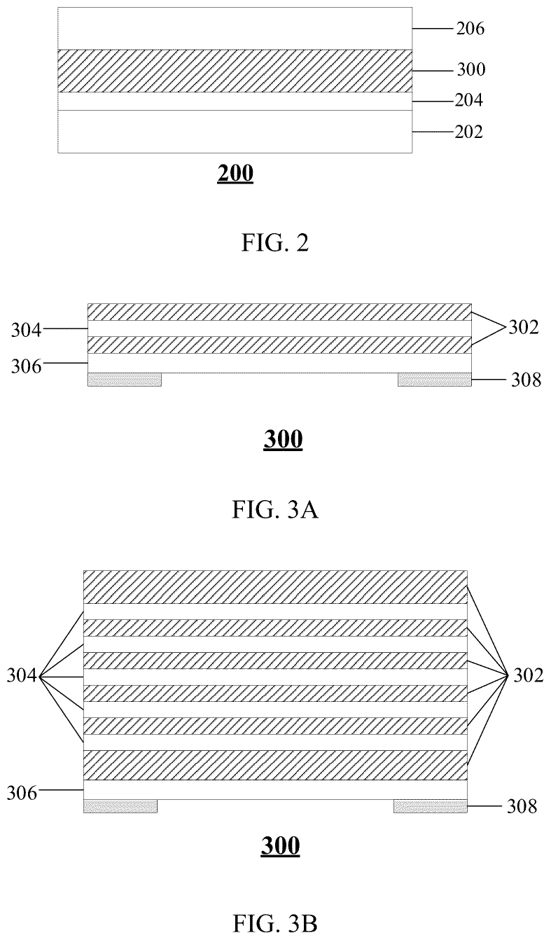

FIG. 2 shows a schematic diagram of a structure of an exemplary display module 200 provided by an embodiment of the present disclosure.

As illustrated in FIG. 2, the display module 200 may include a display panel 202 and an optical film layer 300. The optical film layer 300 may be provided on a light emission side of the display panel 202. The display panel 202 may be any type of display panel, for example, a liquid crystal display panel (LCD), an organic light emitting diode display panel (OLED) and the like. In some embodiments, the optical film layer 300 may be fixed to the display panel 202 by an adhesive layer 204. In an exemplary implementation, the adhesive layer 204 may be an optical glue, such as an OCA.

In some embodiments, a cover plate 206 may also be provided in the light emission direction of the optical film layer 300 and configured to protect the display panel 202 and the optical film layer 300 disposed thereon from being damaged by an external force. In some embodiments, the display panel 202 may be an organic light emitting diode display panel, and the cover plate 206 may be made of a flexible material, such as Polyimide (PI). In this way, the display module 200 can be realized as a flexible display with variable shape and wider application range, and the product itself can be lighter and thinner because of the OLED and the flexible cover plate.

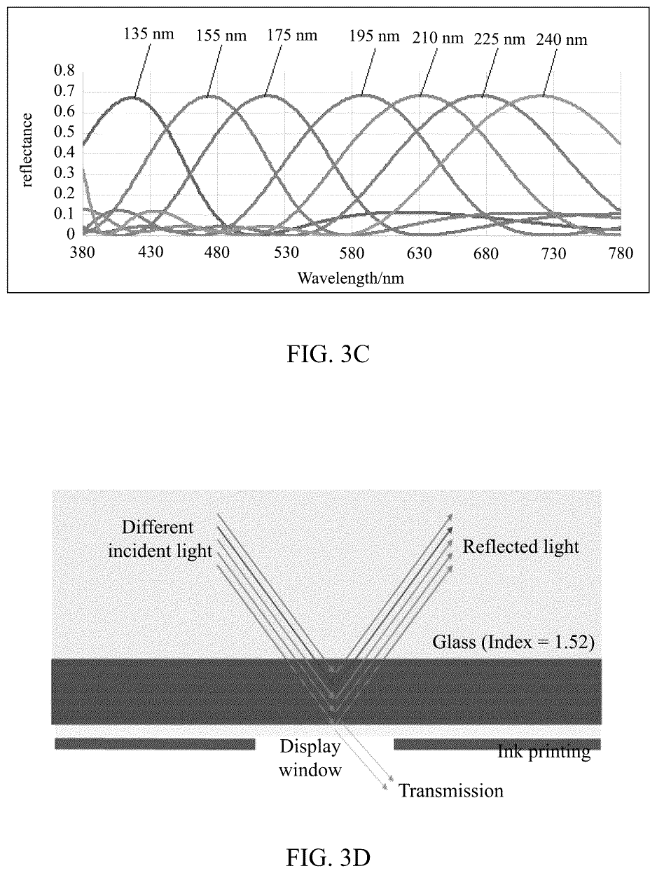

FIG. 3A shows a schematic diagram of a structure of an exemplary optical film layer 300 according to an embodiment of the present disclosure.

As shown in FIG. 3A, the optical film layer 300 includes two first optical layers 302 and one second optical layer 304 arranged in a stacked manner, the first optical layers 302 and the second optical layer 304 are alternately arranged, and the refractive index of a first optical layer 302 is less than the refractive index of the second optical layer 304. In some embodiments, the refractive index of the first optical layer 302 may be 1.4 to 1.6, and the refractive index of the second optical layer 304 may be 1.9 to 2.1. As an exemplary embodiment, the refractive index of the first optical layer 302 may be 1.5, and the refractive index of the second optical layer 304 may be 2.0. In some embodiments, a fabrication material of the first optical layer 302 may be silicon oxide (SiOx), and a fabrication material of the second optical layer 304 may be silicon nitride (SiNx).

In this way, by the collocation of the high/low refractive indices of the optical layers, the optical film layer 300 can achieve better light transmittance in the optical layer portion, so that the display screen of the display panel 202 can be better displayed.

In some embodiments, in order to achieve better light conditioning effects, the optical film layer 300 may include more optical layers, for example, at least three first optical layers and at least two second optical layers. In some embodiments, the optical effect is better, when an optical layer of the optical film layer 300 away from the display panel and an optical layer of the optical film layer 300 close to the display panel are both the first optical layers, that is, both are layers having lower refractive indices.

FIG. 3B shows a schematic diagram of a structure of another exemplary optical film layer 300 according to an embodiment of the present disclosure. As shown in FIG. 3B, in an example, the optical film layer 300 may include six first optical layers 302 and five second optical layers 304. In some embodiments, the optical effect is better when the thickness of the first optical layer (i.e. the uppermost first optical layer 302 in FIG. 3B) away from the display panel and the thickness of the first optical layer (i.e. the lowermost first optical layer 302 in FIG. 3B) close to the display panel are equal.

In some embodiments, the optical effect is better when the thickness of the first optical layer away from the display panel and the thickness of the first optical layer close to the display panel are both greater than or equal to 135 nm. In some embodiments, the optical effect is better when the thicknesses of the second optical layers and the first optical layer sandwiched between the second optical layers are each less than the thickness of the first optical layer away from the display panel. For example, from top to bottom, the ranges of thicknesses of the other layers in the optical film layer 300, except the first optical layer away from the display panel and the first optical layer close to the display panel, may be in sequence as follows: 49 to 53 nm, 69 to 73 nm, 32 to 36 nm, 83 to 87 nm, 73 to 79 nm, 78 to 82 nm, 91 to 96 nm. As an exemplary embodiment, from top to bottom, thicknesses of the other layers in the optical film layer 300, except the first optical layer away from the display panel and the first optical layer close to the display panel, may be in sequence as follows: 51 nm, 71 nm, 34 nm, 85 nm, 76.5 nm, 80 nm, 93.5 nm.

In some embodiments, the color of the reflected light on the optical film layer 300 may be changed by adjusting the thickness of the first optical layer away from the display panel and the thickness of the first optical layer close to the display panel. In this way, color adjustment of the product appearance can be realized by adjusting the thickness of the optical film layer, and other materials are not needed to adjust color of the product appearance.

As shown in FIG. 3C, by adjusting the thicknesses (135 nm to 240 nm) of the first optical layer away from the display panel and the first optical layer close to the display panel, the color of the reflected light on the optical film layer 300 can be easily changed, so that the color change can be realized by the optical layer thickness adjustment.

In some embodiments, in order to better realize the integrated display of the display device to improve the color consistency of the product surface, as shown in FIGS. 3A and 3B, the optical film layer 300 further includes a transflective film 306 on a side close to the display panel, and the transflective film 306 is configured to perform semi-transmissive and semi-reflective optical processing on passing light so as to enhance specularity of the optical film layer 300. In some embodiments, as shown in FIGS. 3A and 3B, the optical film layer 300 may also include an ink layer 308 close to the display panel 202 relative to the transflective film 306, and an orthographic projection of the ink layer 308 in the display panel 202 is located in a non-display area of the display panel 202. In this way, the ink layer can be used to realize the occlusion of the non-display area, and can further enhance the integrated display effect.

In some embodiments, the color of the ink layer 308 is the same as the color of the display product corresponding to the display module 200. In other words, what color is the appearance of the display product itself, and the ink layer 308 can use ink of corresponding color, thus further improving the integrated display effect. For example, the ink layer 308 may use silver ink if the display product appearance is silver, and the ink layer 308 may use white ink if the display product appearance is white, and so on.

In some embodiments, the color difference between a center part and an edge part of the light emission surface of the display module 200 is less than 1, so that the color difference between the center part and the edge part cannot be observed by the naked eye, and the uniformity is good.

In some embodiments, a display product corresponding to the display module 200 may be gold. A value range of brightness L in color difference values may be 65 to 66, a value range of red-green channel value a may be 9 to 10, and a value range of yellow-blue channel value b may be 26 to 27 at a central part of a light emission surface of the display module 200. A value range of brightness L in color difference values may be 65 to 66, a value range of red-green channel value a may be 9 to 10, and a value range of yellow-blue channel value b may be 28 to 29 at an edge part of the light emission surface of the display module 200. The color difference between the central part and the edge part may be less than 1, and the difference cannot be observed by naked eyes.

In some embodiments, a display product corresponding to the display module 200 may be white. A value range of brightness L in color difference values may be 81 to 82, a value range of red-green channel value a may be 0 to 1, and a value range of yellow-blue channel value b may be −2 to −3 at a central part of a light emission surface of the display module 200. A value range of brightness L in color difference values may be 82 to 83, a value range of red-green channel value a may be 0 to 1, and a value range of yellow-blue channel value b may be −2 to −3 at an edge part of the light emission surface of the display module 200. The color difference between the central part and the edge part may be less than 1, and the difference cannot be observed by naked eyes.

In some embodiments, the optical film layer 300 is closer to the mirror film, so that the product has a more aesthetically pleasing appearance and a better integrated display effect.

FIG. 3D shows a schematic diagram of optical principle of a display module 200 provided by an embodiment of the present disclosure.

As shown in FIG. 3D, by using the module obtained by combining the optical film layer and the display panel, the mirror effect and transmission effect are better, and the integration effect of display area and non-display area can be better realized.

Table 1 below shows the color difference test data of a gold product and a white product. When ΔE is less than 1, it is difficult to observe chromatic aberration with naked eyes. As can be seen from Table 1, with the display module of the embodiments of the present disclosure, the color difference between the display center and the edge is less than 1 and the uniformity is good.

TABLE 1

| | Color | | | | |
|---|---|---|---|---|---|
| Product | difference | | | | |
| color | value | L* | a* | b* | ΔE |
| Gold | Center | 65.09 | 9.46 | 26.54 | 0.4 |
| | Edge | 65.62 | 9.03 | 28.65 | |
| White | Center | 81.82 | 0.43 | −2.8 | 0.71 |
| | Edge | 82.39 | 1 | −2.39 | |

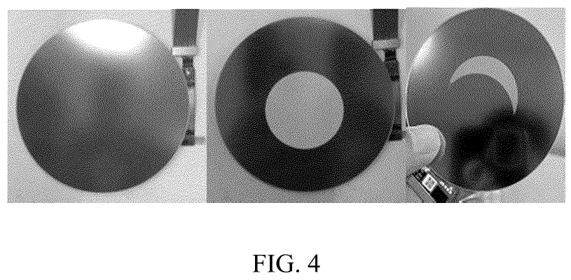

FIG. 4 shows a diagram of display effect of a test sample. As can be seen from FIG. 4, the integrated display effect is relatively good by adopting a display module of an embodiment of the present disclosure.

An embodiment of the present disclosure also provides a display apparatus, which includes any embodiment and the arrangement and combination of the embodiments of the display module 200, and has the corresponding technical effect of embodiments of the display module, which will not be repeated here.

The display apparatus is a product with image display function, such as a display, a television, a billboard, a digital photo frame, a laser printer with display function, a telephone, a mobile phone, a personal digital assistant (PDA), a digital camera, a portable camcorder, a viewfinder, a navigator, a vehicle, a wall with a larger area, a household appliance, and an information inquiry equipment (such as an e-government, a business inquiry equipment of banks, hospitals, electric power departments and the like, a monitor, etc.). In some embodiments, the display apparatus is an electronic product application such as a smart home, an Internet of Things device, and a flexible OLED wearable display, which has a better display effect and a better aesthetic appearance.

In some embodiments, the display apparatus may also include a drive circuit coupled to the display panel 202 and configured to provide an electrical signal to the display panel.

Those ordinary skilled in the art should understand that the discussion on any of the above embodiments is only exemplary and is not intended to imply that the scope of the present disclosure (including the claims) is limited to these examples. Under the concept of the present disclosure, the above embodiments or the technical features in different embodiments may be combined, and the steps may be implemented in any order. There are many other changes in different aspects of embodiments of the present disclosure as described above, which are not provided in details for simplicity.

In addition, in order to simplify the description and discussion and in order not to make embodiments of the present disclosure difficult to be understood, well-known power/ground connections with an Integrated Circuit (IC) chip and other components may or may not be illustrated in the provided drawings. Moreover, an apparatus may be illustrated in a form of a block diagram in order to avoid obscuring embodiments of the present disclosure, which also considers a following fact, that is, details about implementations of apparatuses in these block diagrams highly depend on a platform on which embodiments of the present disclosure will be implemented (that is, these details should be fully within a understanding range of those skilled in the art). With the details (for example, circuits) elaborated to describe the exemplary embodiments of the present disclosure, it is apparent to those skilled in the art that embodiments of the present disclosure may be implemented without these details or in case that these details change. Therefore, these descriptions should be considered illustrative rather than restrictive.

Although the present disclosure is described in combination with embodiments of the present disclosure, many replacements, modifications, and variations of these embodiments are apparent to those ordinary skilled in the art according to the foregoing description. For example, the discussed embodiments may be used for other memory architectures (e.g., a Dynamic RAM (DRAM)).

Embodiments of the present disclosure are intended to cover all such alternatives, modifications, and variations that fall within the broad scope of the appended claims. Therefore, any omissions, modifications, equivalent replacements, improvements, etc., made within the spirit and principle of embodiments of the present disclosure, shall be included within the scope of protection of the present disclosure.

1. A display module, comprising:
a display panel; and
an optical film layer arranged on a light emission side of the display panel;
wherein the optical film layer comprises at least two first optical layers and at least one second optical layer which are arranged in a stacked manner, the first optical layers and the second optical layer are alternately arranged, and a refractive index of a first optical layer is less than a refractive index of the second optical layer.

2. The display module according to claim 1, further comprising: an ink layer and a cover plate, wherein:
the ink layer is arranged on the light emission side of the display panel;
the optical film layer is arranged on a side of the ink layer away from the display panel; and
the cover plate is arranged on a side of the optical film layer away from the ink layer.

3. The display module according to claim 1, wherein the refractive index of the first optical layer is 1.4 to 1.6, and the refractive index of the second optical layer is 1.9 to 2.1.

4. The display module according to claim 3, wherein the refractive index of the first optical layer is 1.5, and the refractive index of the second optical layer is 2.0.

5. The display module according to claim 1, wherein a fabrication material of the first optical layer is silicon oxide, and a fabrication material of the second optical layer is silicon nitride.

6. The display module according to claim 1, wherein the optical film layer comprises at least three first optical layers and at least two second optical layers, and an optical layer of the optical film layer away from the display panel and an optical layer of the optical film layer close to the display panel are both the first optical layers.

7. The display module according to claim 6, wherein a thickness of the first optical layer away from the display panel and a thickness of the first optical layer close to the display panel are equal.

8. The display module according to claim 7, wherein the first optical layer away from the display panel and the first optical layer close to the display panel are configured to change a color of the reflected light on the optical film layer by adjusting thickness.

9. The display module according to claim 6, wherein a thickness of the first optical layer away from the display panel and a thickness of the first optical layer close to the display panel are both greater than or equal to 135 nm.

10. The display module according to claim 6, wherein thicknesses of the second optical layers and a thickness of the first optical layer sandwiched between the second optical layers are each less than a thickness of the first optical layer away from the display panel.

11. The display module according to claim 2, wherein the optical film layer further comprises a transflective film on a side close to the ink layer, and the transflective film is configured to perform semi-transmissive and semi-reflective optical processing on passing light so as to enhance specularity of the optical film layer.

12. The display module according to claim 2, wherein a color of the ink layer is the same as a color of a display product corresponding to the display module.

13. The display module according to claim 12, wherein a color difference between a center part and an edge part of a light emission surface of the display module is less than 1.

14. The display module according to claim 12, wherein the display product is gold, a brightness L in color difference values is 65 to 66, a red-green channel value a is 9 to 10, and a yellow-blue channel value b is 26 to 27 at a center part of a light emission surface of the display module; and a brightness L in color difference values is 65 to 66, a red-green channel value a is 9 to 10, and a yellow-blue channel value b is 28 to 29 at an edge part of the light emission surface of the display module.

15. The display module according to claim 12, wherein the display product is white, a brightness L in color difference values is 81 to 82, a red-green channel value a is 0 to 1, and a yellow-blue channel value b is −2 to −3 at a center part of a light emission surface of the display module; and a brightness L in color difference values is 82 to 83, a red-green channel value a is 0 to 1, and a yellow-blue channel value b is −2 to −3 at an edge part of the light emission surface of the display module.

16. The display module according to claim 1, wherein the optical film layer is a mirror film.

17. The display module according to claim 1, wherein the display panel is an organic light emitting diode display panel and the cover plate is made of a flexible material.

18. A display apparatus, comprising the display module according to claim 1.

19. The display module according to claim 2, wherein the refractive index of the first optical layer is 1.4 to 1.6, and the refractive index of the second optical layer is 1.9 to 2.1.

20. The display module according to claim 2, wherein the optical film layer comprises at least three first optical layers and at least two second optical layers, and an optical layer of the optical film layer away from the display panel and an optical layer of the optical film layer close to the display panel are both the first optical layers.
